(19) United States
(12) Patent Application Publication
(10) Pub. No.: US 2025/0374810 A1
(43) Pub. Date: Dec. 4, 2025

(54) DISPLAY PANEL AND DISPLAY DEVICE

(71) Applicant: Hubei Yangtze Industrial Innovation Center Of Advanced Display Co., Ltd., Wuhan (CN)

(72) Inventors: Li XIAO, Wuhan (CN); Chunpeng ZHANG, Wuhan (CN); Zhenglong ZHANG, Wuhan (CN); Jianxiong XUE, Wuhan (CN)

(73) Assignee: Hubei Yangtze Industrial Innovation Center Of Advanced Display Co., Ltd., Wuhan (CN)

(21) Appl. No.: 19/298,541

(22) Filed: Aug. 13, 2025

(30) Foreign Application Priority Data
May 30, 2025 (CN) 202510724541.7

(51) Int. Cl. H10K 59/80; H10K 59/40

(52) U.S. Cl. CPC H10K 59/879; H10K 59/40

(57) ABSTRACT

Provided are a display panel and a display device. The display panel includes a substrate, a plurality of light-emitting devices, a touch layer, and a refraction layer that are stacked. The touch layer includes a touch line located between adjacent light-emitting devices. The refraction layer includes a first portion, a second portion, and a hollow portion between the first portion and the second portion. Along a direction perpendicular to a plane of the substrate, the first portion overlaps with one of the adjacent light-emitting devices, and the second portion overlaps with the touch line; and an orthographic projection of the hollow portion on the plane of the plurality of light-emitting devices surrounds the light-emitting device corresponding to the first portion. The second portion has a groove, and a surface of the second portion away from the substrate is recessed toward the substrate to form the groove.

### CROSS-REFERENCE TO RELATED APPLICATION

The present disclosure claims priority to Chinese Patent Application No. 202510724541.7, filed on May 30, 2025, the content of which is incorporated herein by reference in its entirety.

### TECHNICAL FIELD

The present disclosure relates to the field of display technologies, and in particular, to a display panel and a display device.

### BACKGROUND

An organic light-emitting diode (OLED) has the characteristics of self-luminescence, and does not need to be provided with a backlight source, so it is lighter and thinner than a liquid crystal display panel. The OLED display panel also has advantages such as high brightness, low power consumption, fast response, high definition, good flexibility, and high luminous efficiency, which can meet new demands of consumers on display technologies. The OLED display panel includes a plurality of film layer structures having different refractive indexes, so that part of light emitted by a light-emitting device is reflected and refracted in various ways to affect the light-emitting brightness. In the related art, a light extraction structure is provided above the light-emitting device to improve the light extraction efficiency of the light-emitting device. However, at present, the patterned refraction layer has problems of large water contact angle and film layer wrinkling in a module section, which affects the product yield.

### SUMMARY

Embodiments of the present disclosure provide a display panel and a display device to solve the technical problems of reducing a water contact angle of a refraction layer in a module section and improving wrinkles of the refraction layer.

In a first aspect, an embodiment of the present disclosure provides a display panel, including: a substrate and a plurality of light-emitting devices located on a side of the substrate, a touch layer located on a side of the plurality of light-emitting devices away from the substrate, and a refraction layer located on a side of the touch layer away from the substrate. The plurality of light emitting devices include a first light-emitting device and a second light-emitting device that are adjacent to each other. The touch layer includes a touch line, and an orthographic projection of the touch line on a plane of the plurality of light-emitting devices is located between the first light-emitting device and the second light-emitting device. The refraction layer includes a first portion, a second portion, and a hollow portion between the first portion and the second portion. Along a direction perpendicular to a plane of the substrate, the first portion overlaps with one of the adjacent light-emitting devices, and the second portion overlaps with the touch line. An orthographic projection of the hollow portion on the plane of the plurality of light-emitting devices surrounds the light-emitting device corresponding to the first portion. The second portion has a groove, and a surface of the second portion away from the substrate is recessed toward the substrate to form the groove.

In a second aspect, an embodiment of the present disclosure provides a display device, including a display panel. The display panel includes: a substrate and a plurality of light-emitting devices located on a side of the substrate, wherein the plurality of light-emitting devices include a first light-emitting device and a second light-emitting device that are adjacent to each other; a touch layer located on a side of the plurality of light-emitting devices away from the substrate, where the touch layer includes a touch line, and an orthographic projection of the touch line on a plane of the plurality of light-emitting devices is located between the first light-emitting device and the second light-emitting device; and a refraction layer located on a side of the touch layer away from the substrate, where the refraction layer includes a first portion, a second portion, and a hollow portion between the first portion and the second portion, along a direction perpendicular to a plane of the substrate, the first portion overlaps with one of the adjacent light-emitting devices, the second portion overlaps with the touch line, and an orthographic projection of the hollow portion on the plane of the plurality of light-emitting devices surrounds the light-emitting device corresponding to the first portion. The second portion has a groove, and a surface of the second portion away from the substrate is recessed toward the substrate to form the groove.

### BRIEF DESCRIPTION OF DRAWINGS

In order to more clearly illustrate technical solutions of embodiments of the present disclosure, the accompanying drawings used in the embodiments are briefly described below. It should be noted that the accompanying drawings described below are merely some embodiments of the present disclosure, and other drawings may be obtained by those skilled in the art according to these drawings.

FIG. 1 is a schematic cross-sectional diagram of a display panel in the related art;

FIG. 2 is a schematic diagram of a display panel according to an embodiment of the present disclosure;

FIG. 3 is an enlarged schematic diagram of an area Q1 shown in FIG. 2;

FIG. 4 is a schematic cross-sectional diagram along a line A-A′ shown in FIG. 3;

FIG. 5 is another schematic cross-sectional diagram along a line A-A′ shown in FIG. 3;

FIG. 6 is another partial schematic diagram of a display panel according to an embodiment of the present disclosure;

FIG. 7 is a schematic diagram of a manufacturing principle of a groove in a display panel according to an embodiment of the present disclosure;

FIG. 8 is another partial schematic diagram of a display panel according to an embodiment of the present disclosure;

FIG. 9 is another partial schematic diagram of a display panel according to an embodiment of the present disclosure;

FIG. 10 is another partial schematic diagram of a display panel according to an embodiment of the present disclosure;

FIG. 11 is another partial schematic diagram of a display panel according to an embodiment of the present disclosure;

FIG. 12 is another partial schematic diagram of a display panel according to an embodiment of the present disclosure;

FIG. 13 is another partial schematic diagram of a display panel according to an embodiment of the present disclosure; and

FIG. 14 is a schematic diagram of a display device according to an embodiment of the present disclosure.

### DESCRIPTION OF EMBODIMENTS

In order to more clearly illustrate objectives, technical solutions, and advantages of embodiments of the present disclosure, the technical solutions in the embodiments of the present disclosure are clearly and completely described in detail with reference to the drawings. It should be noted that the embodiments described are only some rather than all of the embodiments of the present disclosure. Based on the embodiments of the present disclosure, all other embodiments obtained by those ordinary skilled in the art shall fall within a scope of the present disclosure.

Terms used in the embodiments of the present disclosure are only for the purpose of describing specific embodiments, but not intended to limit the present disclosure. Singular forms of “a/an”, “said” and “the” used in the embodiments of the present disclosure and the appended claims are also intended to include plural forms thereof, unless explicitly noted otherwise in the context.

Various modifications and changes may be made to the present disclosure without departing from the scope of the disclosure. Accordingly, the present disclosure is intended to cover the modifications and variations of the present disclosure that fall within the scope of corresponding claims (claimed technical solutions) and their equivalents. It should be noted that the implementations provided in the embodiments of the present disclosure may be combined with each other if no conflict occurs.

FIG. 1 is a schematic cross-sectional diagram of a display panel in the related art. As shown in FIG. 1, the display panel includes a substrate 00, and a light-emitting device 01, a touch line 02, a first refraction layer 03, and a second refraction layer 04 that are located on a side of the substrate 00. The touch lines 02 are wired between adjacent light-emitting devices 01. The first refraction layer 03 is a patterned film layer. The first refraction layer 03 and the second refraction layer 04 above the first refraction layer 03 cooperate with each other to refract the large-angle light emitted by the light-emitting device 01, which may improve the light-emitting efficiency of the light-emitting device 01.

The display panel has problems such as the water contact angle of the first refraction layer 03 exceeding the specification and wrinkles in the pattern of the first refraction layer 03 during the module manufacturing process, which affects the product yield. By analyzing the causes of the technical problems, it is considered that the first refraction layer 03 is currently a patterned film layer, which results in a reduction in the contact area between the water droplet and the first refraction layer 03 during the water contact angle test, making the water contact angle increase beyond the design specification. Further, after the patterning process of the first refraction layer 03, a protective film needs to be attached to the first refraction layer 03, and the module is transferred by adsorbing one side of the protective film with a suction nozzle. Since there is air between the protective film and the hollow area of the first refraction layer 03, the force on the module is uneven when the suction nozzle adsorbs, and the air in the hollow area may squeeze the pattern of the first refraction layer 03, causing wrinkles in the film layer.

In order to solve the problems existing in the related art, an embodiment of the present disclosure provides a display panel, by improving the morphology of the refraction layer above the light-emitting device, and arranging the groove in the refraction layer in an area not overlapping with the light-emitting device, the groove is used to increase the surface area of the refraction layer and reduce the water contact angle, and the groove may also be used to release stress, avoiding film layer wrinkling caused by excessive local stress during the module process, thereby improving the product yield.

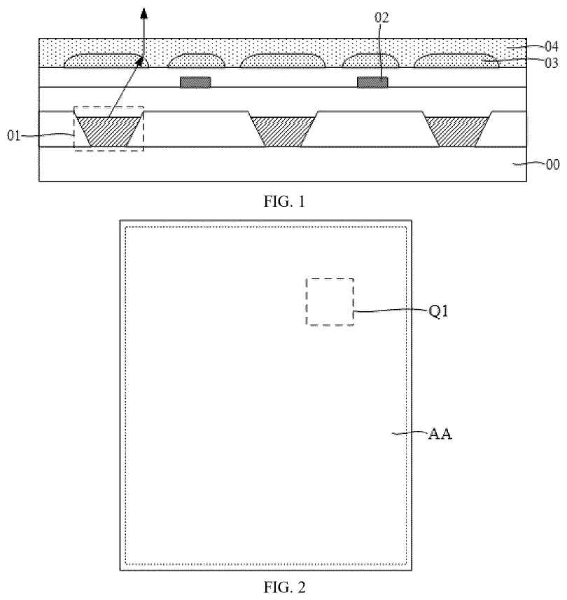

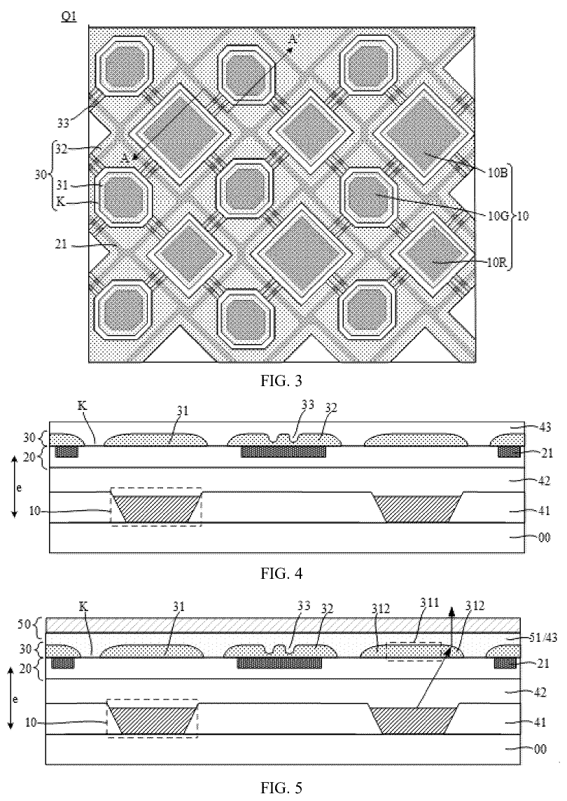

FIG. 2 is a schematic diagram of a display panel according to an embodiment of the present disclosure, FIG. 3 is an enlarged schematic diagram of an area Q1 shown in FIG. 2, and FIG. 4 is a schematic cross-sectional diagram along a line A-A′ shown in FIG. 3.

As shown in conjunction with FIG. 2 and FIG. 3, the display panel includes a display area AA including a plurality of light-emitting devices 10, and the light-emitting devices 10 include a red light-emitting device 10R, a green light-emitting device 10G, and a blue light-emitting device 10B. FIG. 3 merely schematically shows the arrangement and shape of the light-emitting devices 10, which is not intended to limit the present disclosure. FIG. 3 merely schematically shows the arrangement of the light-emitting devices 10 and the touch lines 21 routed between adjacent light-emitting devices 10, and it is seen that the touch lines 21 are cross-connected to form a grid-like wiring.

As shown in FIG. 4, the display panel includes a substrate 00, and a plurality of light-emitting devices 10 are located on one side of the substrate 00. A touch layer 20 is located on a side of the light-emitting devices 10 away from the substrate 00. Each of the light-emitting devices 10 includes a first electrode, a light-emitting layer, and a second electrode that are stacked. A material of the light-emitting layer includes an inorganic light-emitting material or an organic light-emitting material. In an example, the display panel further includes an encapsulation layer 42 located on a side of the light-emitting devices 10 away from the substrate 00. The encapsulation layer 42 is configured to isolate water and oxygen from corroding the light-emitting device 10, thereby prolonging the service life of the light-emitting device 10.

The touch layer 20 includes a touch line 21. An orthographic projection of the touch line 21 on a plane of the light-emitting devices 10 is located between adjacent light-emitting devices 10. In order to illustrate the positional relationship between the touch line 21 and the light-emitting device 10, the present disclosure defines the plane of the light-emitting devices 10. In fact, the light-emitting device 10 has a certain thickness in a direction e perpendicular to a plane of the substrate 0, and the light-emitting device 10 is not a two-dimensional structure without a thickness. Herein, the plane of the light-emitting devices 10 may be understood as the film layer of the light-emitting devices 10. The position of the touch line 21 may also be understood from another perspective. As shown in FIG. 4, the display panel further includes a pixel definition layer 41. The pixel definition layer 41 has an opening, and a light-emitting device 10 is located in the opening of the pixel definition layer 41. In the direction e perpendicular to the plane of the substrate 00, the touch line 21 overlaps with the pixel definition layer 41. That is, from the top view of FIG. 3, touch lines 21 are routed between adjacent light-emitting devices 10. The touch lines 21 with intersecting extension directions form grid-like traces as touch electrodes. A plurality of touch electrodes are provided in the display area AA, and the plurality of touch electrodes cooperate with each other to achieve the touch function of the display panel.

The display panel further includes a refraction layer 30 located on a side of the touch layer 20 away from the substrate 00. The refraction layer 30 includes a first portion 31, a second portion 32, and a hollow portion K between the first portion 31 and the second portion 32. Along the direction e perpendicular to the plane of the substrate 00, the first portion 31 overlaps with one of the adjacent light-emitting devices 10, and the second portion 32 overlaps with the touch line 21. It is seen from FIG. 3 that an orthographic projection of the hollow portion K on the plane of the light-emitting devices 10 surrounds the light-emitting device 10 corresponding to the first portion 31. An optical auxiliary layer 43 is located on a side of the refraction layer 30 away from the substrate 00, and the optical auxiliary layer 43 cooperates with the refraction layer 30 to refract the large-angle light emitted by the light-emitting devices 10, thereby improving the light-emitting efficiency of the light-emitting devices 10. The second portion 32 has a groove 33, and a surface of the second portion 32 away from the substrate 00 is recessed toward the substrate 00 to form the groove 33. It is understood that the groove 33 does not penetrate through the second portion 32 in the direction e perpendicular to the plane of the substrate 00. The shape and the number of the grooves 33 in FIG. 3 are only schematically shown.

In the display panel according to the embodiments of the present disclosure, the refraction layer 30 located above the light-emitting devices 10 is a patterned film layer. The first portion 31 of the refraction layer 30 overlaps with the light-emitting device 10, and the second part 32 overlaps with the touch line 21 between adjacent light-emitting devices 10. The groove 33 formed on the second portion 32 may increase the surface area of the refraction layer 30 away from the substrate 00. According to the Cassie-Baxter formula: cos θ_{c}=f·cos θ−1+f, where θ_{c} is an apparent contact angle (i.e., the water contact angle), f is a solid phase fraction of the surface (representing a ratio of the area where the liquid droplet contacts the solid surface), and θ is an intrinsic contact angle of the solid contained material, it is known that when the surface area of the refraction layer 30 away from the substrate 00 increases, the contact area between the liquid droplet and the refraction layer 30 increases during testing, so that f increases, cos θ_{c} increases, and the corresponding water contact angle θ_{c} decreases. The groove 33 formed on the second portion 32 may increase the surface area of the refraction layer 30 away from the substrate 00, and increase the contact area between the surface of the refraction layer 30 away from the substrate 00 and the liquid droplet, effectively reducing the water contact angle, thereby increasing the adhesion between the refraction layer 30 and the film layer above the refraction layer 30. Further, the groove 33 on the second portion 32 may also provide a space for stress release during the module operation, avoiding wrinkles in the pattern of the refraction layer 30 caused by excessive local stress during the module manufacturing process, thereby improving the product yield.

In some embodiments, FIG. 5 is another schematic cross-sectional diagram along a line A-A′ shown in FIG. 3. As shown in FIG. 5, the display panel includes a polarizer 50 located on a side of the refraction layer 30 away from the substrate 00. The polarizer 50 includes an adhesive layer 51 filling the hollow portion K and the groove 33. The adhesive layer 51 is reused as the optical auxiliary layer 43. The adhesive layer 51 cooperates with the refraction layer 30 to refract the large-angle light emitted by the light-emitting device 10, thereby improving the light-emitting efficiency of the light-emitting device 10. When manufacturing the display panel, the polarizer 50 may be attached to the module after the patterning process of the refraction layer 30 is completed, and the adhesive layer 51 of the polarizer 50 has a certain thickness and viscosity. Combined with the design of the groove 33 formed on the second portion 32 in the embodiments of the present disclosure, the contact area between the adhesive layer 51 and the refraction layer 30 may be increased, so that the adhesive layer 51 and the refraction layer 30 are tightly bonded. In the manufacturing process, the optical auxiliary layer does not need to be additionally manufactured in the display panel, which may save the process of the display panel and reduce costs.

In some embodiments, as shown in FIG. 5, the first portion 31 of the refraction layer 30 includes a central portion 311 and an edge portion 312, and the edge portion 312 surrounds the central portion 311. In a direction from the central portion 311 to the edge portion 312, a thickness of the edge portion 312 in the direction e perpendicular to the plane of the substrate 00 gradually decreases. A refractive index of the refraction layer 30 is greater than a refractive index of the adhesive layer 51. When the large-angle light emitted by the light-emitting device 10 is inputted into the adhesive layer 51 at the interface where the edge portion 312 is in contact with the adhesive layer 51, the light is deflected toward the direction e perpendicular to the plane of the substrate 00, so that more light emitted by the light-emitting device 10 may be emitted from the light-emitting surface of the display panel, thereby improving the light-emitting efficiency of the light-emitting device 10 and reducing the power consumption of the display panel.

In some embodiments, as shown in FIG. 5, the second portion 32 is in contact with a surface of the touch line 21 away from the substrate 00. That is, there is no insulating layer between the touch line 21 and the second portion 32. When manufacturing the display panel, the refraction layer 30 may be directly manufactured after the patterning process of the touch lines 21 is completed, thereby saving one process of the insulating layer and facilitating reducing the thickness of the display panel. The second portion 32 covering the touch line 21 may protect the touch line 21 and prevent the adhesive layer 51 of the polarizer 50 from corroding the touch line 21. In the embodiments of the present disclosure, although the groove 33 is formed in the second portion 32, the material of the refraction layer remains at the bottom of the groove 33, which may still isolate the touch line 21 from the adhesive layer 51 of the polarizer 50, thereby preventing the adhesive layer 51 from corroding the touch line 21.

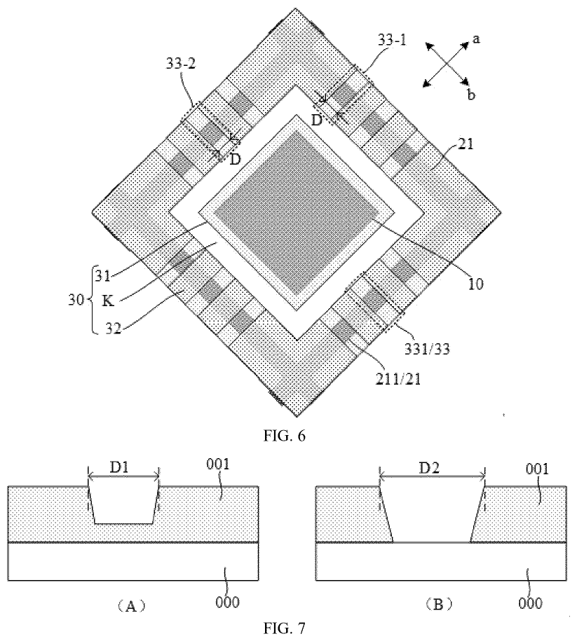

In the embodiments of the present disclosure, the groove 33 has a certain size in its extension direction and a certain width, and grooves 33 arranged at different positions in the display area may have different extension directions. The width of the groove 33 is schematically described by taking a local position as an example. FIG. 6 is another partial schematic diagram of a display panel according to an embodiment of the present disclosure. FIG. 6 schematically shows a top view of a position where one light-emitting device 10 is located, in which are shown a touch line 21, a first portion 31 and a second portion 32 in the refraction layer 30, and a groove 33 on the second portion 32. As shown in FIG. 6, a groove 33-1 extends along the first direction a, a notch width of the groove 33-1 in the second direction b is D, and D is less than the material resolution of the refraction layer 30. The first direction a and the second direction b intersect with each other, and the first direction a and the second direction b are respectively parallel to the plane of the substrate 00. The material resolution refers to the minimum size of the pattern formed by exposure during exposure and development process, which is usually expressed in unit length (such as micrometers).

FIG. 7 is a schematic diagram of a manufacturing principle of a groove in a display panel according to an embodiment of the present disclosure. The film layer 001 is patterned on the substrate 000 by an exposure-development process. As shown in FIG. 7(A), when a width of a preset exposure area on the film layer 001 parallel to the paper surface is D1, and D1 is less than the material resolution of the film layer 001, after exposure and development, a groove is formed on the film layer 001, and the material of the film layer 001 remains at the bottom of the groove. As shown in FIG. 7(B), when the width of the preset exposure area on the film layer 001 parallel to the paper surface is D2, and D2 is greater than the material resolution of the film layer 001, after exposure and development, an opening is formed on the film layer 001, and the bottom of the opening may expose the substrate 000.

In the embodiments of the present disclosure, a width of the groove 33 in one direction is configured to be smaller than the material resolution of the refraction layer 30. The requirement for a notch width of the groove 33 may ensure that the material of the refraction layer at the preset forming position of the groove is not completely exposed during the exposure process. The groove 33 is formed after development, and the material of the refraction layer remains at the bottom of the groove 33, so that the second portion 32 at the position of the groove 33 may still cover the substrate below thereunder well. The refraction layer 30 may be manufactured into the first portion 31, the second portion 32, the hollow portion K, and the groove 33 that is located on the second portion 32 in one patterning process, which simplifies the manufacturing process.

Further, as shown in FIG. 6, an extension direction of the groove 33-2 is different from an extension direction of the groove 33-1, and a notch width of the groove 33-2 in a direction perpendicular to the extension direction of the groove 33-2 is D, where D is less than the material resolution of the refraction layer 30. In the embodiments of the present disclosure, the extension directions of the grooves 33 arranged at different positions may be different. The extension direction of the groove 33 at a specific position may be determined first, and then a notch width of the groove 33 in the direction perpendicular to the extension direction thereof may be determined.

In some embodiments, as shown in the top view of FIG. 6, the shape of the notch of the groove 33 is roughly rectangular in the top view. The top view pattern of the groove 33 includes a long side and a short side. The extension direction of the long side of the pattern is the first direction in which the groove 33 extends, and the extension direction of the short side of the pattern is the corresponding second direction. A notch width of the groove 33 in the extension direction of the short side of the pattern is less than the material resolution, and a notch width of the groove 33 in the extension direction of the long side of the pattern is greater than the material resolution. The shape of the notch of the groove 33 is roughly rectangular in the top view, and the notch width of the groove 33 in the extension direction of the short side of the pattern is smaller than the material resolution. On the one hand, it may ensure that the material of the refraction layer remains at the bottom of the groove 33 after the exposure and development process is completed, so that the refraction layer may better cover the substrate below the refraction layer. On the other hand, an area size of the groove 33 may be relatively large. The groove 33 may further increase the surface area of the refraction layer 30 away from the substrate 00 to effectively reduce the water drop angle, and better release local stress during the module manufacturing process to prevent film layer wrinkling.

In some embodiments, as shown in FIG. 6, the groove 33 includes a first groove 331. At least one end of the first groove 331 in the extension direction thereof is connected to the hollow portion K. During the module manufacturing process of the display panel, after the patterning process of the refraction layer 30 is completed, a protective film needs to be attached to the refraction layer 30, and then a suction nozzle is used to adsorb one side of the protective film to transfer the module. The second portion 32 is provided with a first groove 331 connected to the hollow portion K, which may increase a space for air circulation between the protective film and the refraction layer 30 when the suction nozzle adsorbs, and may better release the stress, thereby avoiding wrinkles in the pattern of the refraction layer 30 caused by local stress extrusion.

As shown in FIG. 6, the touch line 21 includes a first touch line 211, and an extension direction of the first groove 331 intersects with an extension direction of the first touch line 211. FIG. 6 is a partial top view of the display panel, where the top view direction is parallel to the direction e perpendicular to the plane of the substrate 00. It is seen from FIG. 6 that along the direction e perpendicular to the plane of the substrate 00, the first groove 331 overlaps with the first touch line 211. Combined with FIG. 3, the touch lines 21 in the display panel are traced between adjacent light-emitting devices 10, the second portion 32 overlaps with the touch lines 21, and a hollow portion K further needs to be provided between the second portion 32 and the first portion 31, so that there are certain requirements on the size and position of the second portion 32. In the embodiments of the present disclosure, the first groove 331 formed on the second portion 32 overlaps with the first touch line 211, and at least one end of the first groove 331 is connected to the hollow portion K, so that a first groove 331 with a relatively large area size may be manufactured on the second portion 32. The first groove 331 may further increase the surface area of the refraction layer 30 away from the substrate 00 to effectively reduce the water contact angle, and better release local stress during the module manufacturing process to prevent film layer wrinkling.

It should be noted that, in the embodiments of the present disclosure, the first touch line 211 is named according to the type of the groove 33 overlapping therewith. For example, at least one end of the first groove 331 in the extension direction thereof is connected to the hollow portion K, and the touch line 21 overlapping with the first groove 331 is named as the first touch line 211. As shown in the embodiments of FIG. 6, four touch lines 21 are shown, and the four touch lines 21 extend in the same direction in pairs. The four touch lines 21 are all first touch lines 211. Further, in the following embodiments, the touch line 21 also includes a second touch line, and the groove 33 overlapping with the second touch line does not connect to the hollow portion K.

As shown in FIG. 6, the first touch line 211 overlaps with at least two first grooves 331 arranged in the extension direction thereof. In this way, by increasing the number of the first grooves 331, the surface area of the refraction layer 30 away from the substrate 00 may be increased more, thereby increasing the adhesion between the refraction layer 30 and the film layer above the refraction layer 30. Further, stress may be released at more positions, thereby effectively avoiding wrinkles in the pattern of the refraction layer 30 during the module manufacturing process.

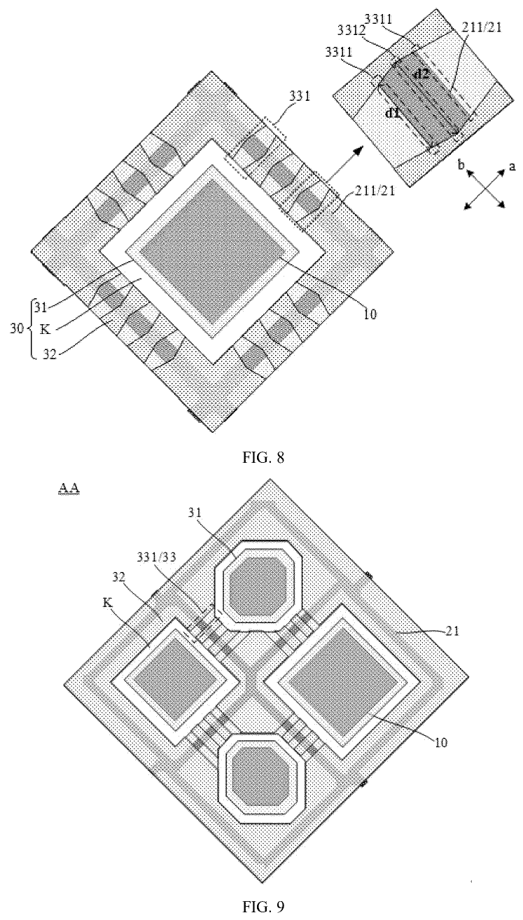

In some other embodiments, FIG. 8 is another partial schematic diagram of a display panel according to an embodiment of the present disclosure, and FIG. 8 schematically shows a top view of a position of one light-emitting device 10. As shown in FIG. 8, the groove 33 includes a first groove 331, and at least one end of the first groove 331 in the extension direction thereof is connected to the hollow portion K. FIG. 8 further shows an enlarged schematic diagram of a position of one first groove 331. Taking the extension direction of the first groove 331 at the enlarged position being the first direction a as an example, the first direction a is parallel to the plane of the substrate 00. The first groove 331 includes a first sub-part 3311 and a second sub-part 3312. As is seen from the top view of FIG. 8, along the direction perpendicular to the plane of the substrate 00, at least one side edge of the first touch line 211 overlaps with the first sub-part 3311. In a second direction b, a width of the first sub-part 3311 is d1, and a width of the second sub-part 3312 is d2, where d1<d2, and d2 is less than the material resolution of the refraction layer 30. The second direction b intersects with the first direction a, and the second direction b is parallel to the plane of the substrate 00. In the embodiments, d1<d2, and d2 is smaller than the material resolution of the refraction layer 30, which makes that the first portion 31, the second portion 32, the hollow portion K, and the first groove 331 on the second portion 32 of the refraction layer 30 may be manufactured in one patterning process when manufacturing the display panel, and the position of the first groove 331 is not completely exposed, so that the material of the refraction layer remains at the bottom of the first groove 331. Further, the notch width of the first groove 331 overlapping with the side edge of the first touch line 211 is relatively smaller, so that the amount of residual film exposed at the position overlapping with the side edge of the first touch line 211 is larger, ensuring that the side edge of the first touch line 211 is well coated, and avoiding corrosion due to poor coating of the side edge of the first touch line 211.

In some embodiments, as shown in FIG. 8, along the direction perpendicular to the plane of the substrate 00, two side edges of the first touch line 211 respectively overlap with one first sub-part 3311. At least at a position where the first groove 331 overlaps with the first touch line 211, a second sub-part 3312 is provided between the two first sub-parts 3311. In the embodiments, two side edges of the first touch line 211 are configured to respectively overlap with one first sub-part 3311, so that an extension direction of the first groove 331 intersects with an extension direction of the first touch line 211, and a first groove 331 with a relatively large area size may be manufactured on the second portion 32, ensuring that the first groove 331 may further increase the surface area of the refraction layer 30 away from the substrate 00 to effectively the water contact angle, and better release local stress during the module manufacturing process to prevent film layer wrinkling. Further, it is ensured that relatively thicker materials of the refraction layer are retained at least on the two side edges of the first touch line 211, so as to well coat the side edges of the first touch line 211, thereby avoiding corrosion due to poor coating of the side edge of the first touch line 211.

In an example, as shown in the enlarged view in FIG. 8, the extension direction of the first groove 331 intersects with the extension direction of the touch line 21 overlapping therewith, and the notch width of the first groove 331 in the direction perpendicular to the extension direction thereof gradually increases and then gradually decreases. Further, a maximum notch width of the first groove 331 perpendicular to the extension direction thereof is smaller than the material resolution of the refraction layer 30.

In some embodiments, FIG. 9 is another partial schematic diagram of a display panel according to an embodiment of the present disclosure. FIG. 9 schematically shows positions of four light-emitting devices 10 in the display area AA. As shown in FIG. 9, a first groove 331 is provided between two adjacent light-emitting devices 10, and at least one first groove 331 is respectively connected to one hollow portion K at both ends in its extension direction. That is, one first groove 331 is connected to two adjacent hollow portions K. Such an arrangement allows a larger space for air circulation between the protective film and the refraction layer 30 when the module is transferred by adsorbing one side of the protective film with the suction nozzle during the module manufacturing process, which is more conducive to local stress release, thereby effectively avoiding wrinkles in the pattern of the refraction layer 30 caused by local stress extrusion.

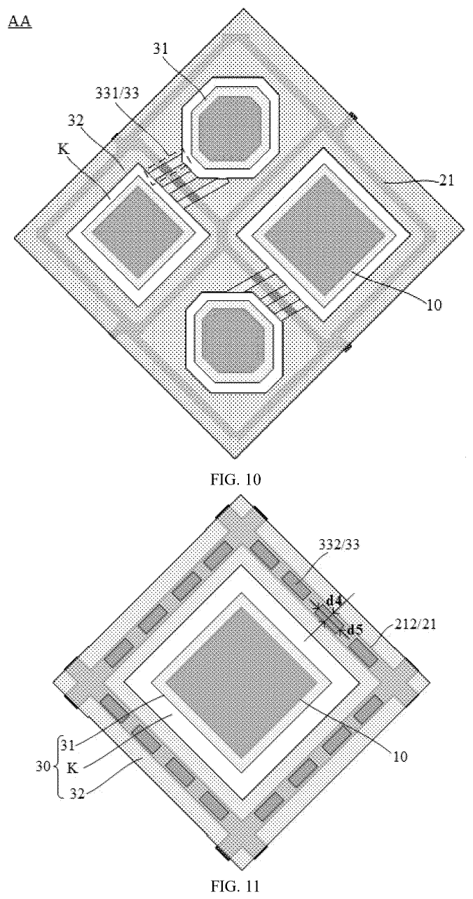

In the embodiments of FIG. 9, an extension direction of the first groove 331 is substantially perpendicular to the touch line 21 overlapping therewith. In other words, the extension direction of the first groove 331 forms a right-angle included angle with the touch line 21 overlapping therewith. In some other embodiments, an acute included angle is formed between the extension direction of the first groove 331 and the touch line 21 overlapping therewith. FIG. 10 is another schematic diagram of a display panel according to some embodiments of the present disclosure. FIG. 10 schematically shows positions of four light-emitting devices 10 in the display area AA. As shown in FIG. 10, a groove 33 is provided on the second portion 32, and at least one first groove 331 is connected to one hollow portion K at both ends in its extension direction. An acute included angle is formed between the extension direction of the first groove 331 and the touch line 21 overlapping therewith.

In some embodiments, FIG. 11 is another partial schematic diagram of a display panel according to an embodiment of the present disclosure, and FIG. 11 schematically shows a top view of a position of one light-emitting device 10. As shown in FIG. 11, the groove 33 includes a second groove 332, and the touch line 21 includes a second touch line 212. The touch line 21 overlapping with the second groove 332 is named as the second touch line 212. FIG. 11 is a partial top view of the display panel. In the top view, the second touch line 212 coincides with its orthographic projection on the plane of the substrate 00, and the second groove 332 coincides with its orthographic projection on the plane of the substrate 00. It is seen from FIG. 11 that an orthographic projection of the second touch line 212 on the substrate 00 is a first projection, an orthographic projection of the second groove 332 on the substrate 00 is a second projection, and the first projection covers the second projection. It is seen that in the direction perpendicular to the extension direction of the second touch line 212, an edge of the second projection is spaced a certain distance from an edge of the first projection. That is, in the top view, in the direction perpendicular to the extension direction of the second touch line 212, a distance between a notch edge of the second groove 332 and a side edge of the second touch line 212 is greater than zero. In the embodiments, the second groove 332 is formed at a position overlapping with the second touch line 212, and the material of the refraction layer under the second groove 332 may well cover the second touch line 212. For example, when a polarizer is attached to the refraction layer 30, the adhesive layer of the polarizer may be well isolated from the second touch line 212, thereby preventing the second touch line 212 from being corroded.

In some embodiments, as shown in FIG. 11, in the direction perpendicular to the extension direction of the second touch line 212, a notch width of the second groove 332 is d4, and d4 is less than the material resolution of the refraction layer 30. In this way, the first portion 31, the second portion 32, the hollow portion K, and the second groove 332 on the second portion 32 of the refraction layer 30 may be manufactured in one patterning process. Due to the certain requirements for the notch width of the second groove 332, the material of the refraction layer at the preset forming position of the groove is not completely exposed during the exposure process, and the second groove 332 is formed after development is completed, so that the material of the refraction layer may be reserved at the bottom of the second groove 332 to well cover the second touch line 212, thereby preventing the second touch line 212 from being exposed and corroded.

In some embodiments, as shown in FIG. 11, in the direction perpendicular to the extension direction of the second touch line 212, the notch width of the second groove 332 is d4, and in the extension direction of the second touch line 212, the notch width of the second groove 332 is d5, where d5>d4. Such an arrangement may make the area size of the single second groove 332 relatively large, so that the second groove 332 increases the surface area of the refraction layer 30 away from the substrate more, which has a more positive benefit in reducing the water contact angle.

In some embodiments, as shown in the top view of FIG. 11, the first projection of the second touch line 212 covers the second projections of at least two second grooves 332 arranged along the extension direction of the second touch line 212. That is, the second touch line 212 overlaps with at least two second grooves 332. This embodiment may not only increase the surface area of the refraction layer 30 away from the substrate more, improving the bonding strength between the refraction layer 30 and the film layer above the refraction layer 30, but also be equivalent to providing multiple stress release positions on the refraction layer 30, effectively avoiding wrinkles in the pattern of the refraction layer 30 during the module manufacturing process.

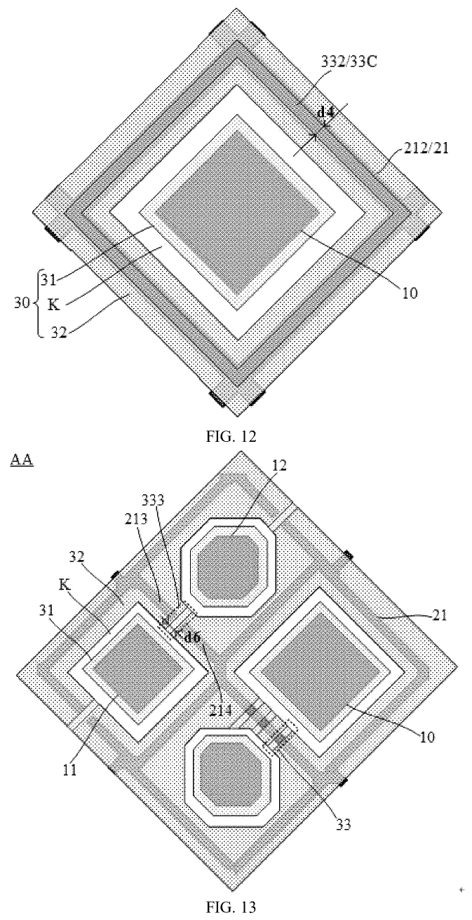

In other embodiments, FIG. 12 is another partial schematic diagram of a display panel according to an embodiment of the present disclosure. FIG. 12 schematically shows a top view of a position of one light-emitting device 10. As shown in FIG. 12, four second grooves 332 are connected end to end to form an annular groove 33C, and an orthographic projection of the annular groove 33C on the plane of the light-emitting device 10 surrounds a hollow portion K. In the direction perpendicular to the extension direction of the second touch line 212, the notch width of the second groove 332 is d4, and d4 is less than the material resolution of the refraction layer 30. In this embodiment, by providing the annular groove 33C, the touch line 21 under the annular groove 33C may be well covered by the material of the refraction layer, thereby preventing the touch line 21 from being viewed from above. Further, a side surface area of the annular groove 33C is larger, which is more beneficial to increase the surface area of the refraction layer 30 away from the substrate, and has a more positive benefit in reducing the water contact angle.

In other embodiments, FIG. 13 is another partial schematic diagram of a display panel according to an embodiment of the present disclosure. As shown in FIG. 13, the light-emitting devices 10 include a first light-emitting device 11 and a second light-emitting device 12 that are adjacent to each other, and the touch line 21 includes a third touch line 213 and a fourth touch line 214. An orthographic projection of the third touch line 213 and an orthographic projection of the fourth touch line 214 on the plane of the light-emitting device 10 are located between the first light-emitting device 11 and the second light-emitting device 12. There is a break between the third touch line 213 and the fourth touch line 214. A plurality of touch electrodes need to be produced in the entire display area. The intersecting touch lines 21 form grid-like touch electrodes, and adjacent touch electrodes need to be disconnected, or dummy electrodes need to be produced between adjacent touch electrodes. Therefore, there are a plurality of positions in the display area where breaks are formed between the third touch line 213 and the fourth touch line 214 as shown in FIG. 13.

As shown in FIG. 13, the groove 33 includes a third groove 333. In the top view, the third groove 333 coincides with its orthographic projection on the plane of the touch layer 20. It is seen from the top view of FIG. 13 that the orthographic projection of the third groove 333 on the touch layer 20 penetrates through the break. The second portion 32 may well cover broken edges of the third touch line 213 and the fourth touch line 214. Since no touch line exists at the break position, when the third groove 333 is manufactured at the break position, the thickness requirement for the material of the refraction layer remained below the third groove 333 is relatively low, so that the third groove 333 is easier to manufacture, and the product yield is higher.

In some embodiments, as shown in FIG. 13, in the extension direction of the third touch line 213 or the fourth touch line 214, the notch width of the third groove 333 is d6, and d6 is less than the material resolution of the refraction layer 30. In this way, the first portion 31, the second portion 32, the hollow portion K, and the third groove 333 on the second portion 32 of the refraction layer 30 may be manufactured in one patterning process. Due to the certain requirement for the notch width of the third groove 333, the material of the refraction layer at the preset forming position of the third groove is not completely exposed during the exposure process, and the third groove 333 is formed after development is completed. The material of the refraction layer is retained at the bottom of the third groove 333, so as to ensure that the broken edge of the touch line at the break position may also be well covered by the second portion 32, thereby preventing the touch line from being exposed and corroded.

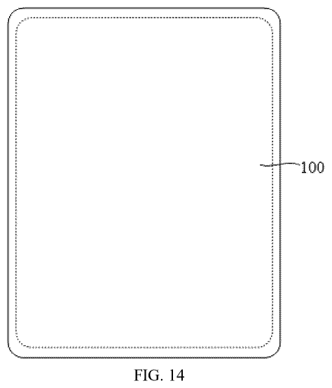

Based on the same inventive concept, an embodiment of the present disclosure further provides a display device. FIG. 14 is a schematic diagram of a display device according to an embodiment of the present disclosure. As shown in FIG. 14, the display device includes the display panel 100 provided by any embodiment of the present disclosure. The structure of the display panel 100 has been described in the above embodiments, and will not be repeated herein. The display device according to the embodiments of the present disclosure may be, for example, an electronic device having a display function, such as a tablet, a mobile phone, a computer, or a television.

The above description merely schematically shows some preferred embodiments of the present disclosure and is not intended to limit the present disclosure, and any modification, equivalent substitution, improvement and the like made within a spirit and a principle of the present disclosure shall fall with the scope of the present disclosure.

Finally, it should be noted that, the above-described embodiments are merely for illustrating the present disclosure but not intended to provide any limitation. Although the present disclosure has been described in detail with reference to the above-described embodiments, it should be understood by those skilled in the art that, it is still possible to modify the technical solutions described in the above embodiments or to equivalently replace some or all of the technical features therein, but these modifications or replacements do not cause the essence of corresponding technical solutions to depart from the scope of the present disclosure.

What is claimed is:

1. A display panel, comprising:
a substrate and a plurality of light-emitting devices located on a side of the substrate, wherein the plurality of light-emitting devices comprise a first light-emitting device and a second light-emitting device that are adjacent to each other;
a touch layer located on a side of the plurality of light-emitting devices away from the substrate, wherein the touch layer comprises a touch line, and an orthographic projection of the touch line on a plane of the plurality of light-emitting devices is located between the first light-emitting device and the second light-emitting device; and
a refraction layer located on a side of the touch layer away from the substrate, wherein the refraction layer comprises a first portion, a second portion, and a hollow portion between the first portion and the second portion, wherein, along a direction perpendicular to a plane of the substrate, the first portion overlaps with one of the first light-emitting device and second light-emitting device, the second portion overlaps with the touch line, and an orthographic projection of the hollow portion on the plane of the plurality of light-emitting devices surrounds the light-emitting device overlapped by the first portion,
wherein the second portion has a groove, and a surface of the second portion away from the substrate is recessed toward the substrate to form the groove.

2. The display panel according to claim 1, wherein the groove extends along a first direction, a notch width of the groove in a second direction is smaller than a material resolution of the refraction layer, the first direction and the second direction intersect with each other, and the first direction and the second direction are respectively parallel to the plane of the substrate.

3. The display panel according to claim 1, wherein the groove comprises a first groove, and at least one end of the first groove in an extension direction of the first groove is connected to the hollow portion.

4. The display panel according to claim 3, wherein the touch line comprises a first touch line, and the extension direction of the first groove intersects with an extension direction of the first touch line; and
the first groove overlaps with the first touch line in the direction perpendicular to the plane of the substrate.

5. The display panel according to claim 4, wherein the first touch line overlaps with at least two first grooves arranged in the extension direction of the first touch line.

6. The display panel according to claim 4, wherein the first groove extends along a first direction, and the first direction is parallel to the plane of the substrate;
the first groove comprises a first sub-part and a second sub-part, and along the direction perpendicular to the plane of the substrate, at least one side edge of the first touch line overlaps with the first sub-part; and
in a second direction, a width of the first sub-part is d1, a width of the second sub-part is d2, the second direction intersects with the first direction, and the second direction is parallel to the plane of the substrate;
wherein d1<d2, and d2 is less than a material resolution of the refraction layer.

7. The display panel according to claim 6, wherein two side edges of the first touch line respectively overlap with one first sub-part along the direction perpendicular to the plane of the substrate; and
the second sub-part is arranged between two first sub-parts at least at a position where the first groove overlaps with the first touch line.

8. The display panel according to claim 3, wherein at least one first groove has two ends respectively connected to one hollow portion in an extension direction of the at least one first groove.

9. The display panel according to claim 1, wherein the groove comprises a second groove, and the touch line comprises a second touch line;
an orthographic projection of the second touch line on the substrate is a first projection, an orthographic projection of the second groove on the substrate is a second projection, and the first projection covers the second projection; and
in a direction perpendicular to an extension direction of the second touch line, an edge of the second projection is spaced by a certain distance from an edge of the first projection.

10. The display panel according to claim 9, wherein in the direction perpendicular to the extension direction of the second touch line, a notch width of the second groove is d4, and d4 is less than a material resolution of the refraction layer.

11. The display panel according to claim 9, wherein in the direction perpendicular to the extension direction of the second touch line, a notch width of the second groove is d4; and
along the extension direction of the second touch line, the notch width of the second groove is d5;
wherein d5>d4.

12. The display panel according to claim 9, wherein the first projection covers at least two second projections arranged along the extension direction of the second touch line.

13. The display panel according to claim 9, wherein four second grooves are connected end to end to form an annular groove, and an orthographic projection of the annular groove on the plane of the plurality of light-emitting devices surrounds one hollow portion.

14. The display panel according to claim 1, wherein the touch line comprises a third touch line and a fourth touch line;
an orthographic projection of the third touch line and an orthographic projection of the fourth touch line on the plane of the plurality of light-emitting devices are located between the first light-emitting device and the second light-emitting device;
a break is formed between the third touch line and the fourth touch line; and
the groove comprises a third groove, and an orthographic projection of the third groove on the touch layer penetrates through the break.

15. The display panel according to claim 14, wherein in an extension direction of the third touch line and the fourth touch line, a notch width of the third groove is d6, and d6 is less than a material resolution of the refraction layer.

16. The display panel according to claim 1, wherein the first portion comprises a central portion and an edge portion, and the edge portion surrounds the central portion; and
in a direction from the central portion to the edge portion, a thickness of the edge portion in the direction perpendicular to the plane of the substrate gradually decreases.

17. The display panel according to claim 1, wherein the second portion is in contact with a surface of the touch line away from the substrate.

18. The display panel according to claim 1, further comprising:
a polarizer located on a side of the refraction layer away from the substrate, wherein the polarizer comprises an adhesive layer filling the hollow portion and the groove.

19. The display panel according to claim 18, wherein a refractive index of the refraction layer is greater than a refractive index of the adhesive layer.

20. A display device, comprising a display panel,
wherein the display panel comprises:
a substrate and a plurality of light-emitting devices located on a side of the substrate, wherein the plurality of light-emitting devices comprise a first light-emitting device and a second light-emitting device that are adjacent to each other;
a touch layer located on a side of the plurality of light-emitting devices away from the substrate, wherein the touch layer comprises a touch line, and an orthographic projection of the touch line on a plane of the plurality of light-emitting devices is located between the first light-emitting device and the second light-emitting device; and
a refraction layer located on a side of the touch layer away from the substrate, wherein the refraction layer comprises a first portion, a second portion, and a hollow portion between the first portion and the second portion, along a direction perpendicular to a plane of the substrate, the first portion overlaps with one of the first light-emitting device and second light-emitting device, the second portion overlaps with the touch line, and an orthographic projection of the hollow portion on the plane of the plurality of light-emitting devices surrounds the light-emitting device corresponding to the first portion,
wherein the second portion has a groove, and a surface of the second portion away from the substrate is recessed toward the substrate to form the groove.
